(19) United States
(12) Patent Application Publication
(10) Pub. No.: US 2012/0048347 A1
(43) Pub. Date: Mar. 1, 2012

(54) PHOTOVOLTAIC PANEL

(75) Inventors: Chen-Yu YANG, Keelung City (TW); Chi-Lai Lee, Taoyuan County (TW); Wei-Lun Hsiao, Taoyuan County (TW)

(73) Assignee: Du Pont Apollo Limited, Hong Kong (HK)

(21) Appl. No.: 13/188,465

(22) Filed: Jul. 22, 2011

(30) Foreign Application Priority Data
Aug. 30, 2010 (CN) 201010270438.3

(51) Int. Cl. H01L 31/048

(52) U.S. Cl. 136/251

(57) ABSTRACT

A photovoltaic panel includes a substrate, a photovoltaic array formed on the substrate; two bus bars formed on the substrate and electrically connected to the photovoltaic array; two interconnecting wires connected to the bus bars; two partially-overlapped first insulation films; a first encapsulating film; a rear substrate; and a junction box disposed on the rear substrate. The first insulation films are located between the interconnecting wires and the photovoltaic array. The first encapsulating film covers the photovoltaic array, the bus bars, the interconnecting wires and the first insulation films. The first encapsulating film has two first slits for allowing the interconnecting wires to pass through. The rear substrate covers the first encapsulating film and has at least one opening for allowing the interconnecting wires to pass through. The interconnecting wires are electrically connected between the junction box and the bus bars to output the current produced by the photovoltaic array.

### RELATED APPLICATIONS

This application claims priority to China Application Serial Number 201010270438.3, filed Aug. 30, 2010, which is herein incorporated by reference.

### BACKGROUND

1. Field of Invention

The present invention relates to a photovoltaic panel.

2. Description of Related Art

As a new eco-friendly energy resource, solar energy gradually attracts people's attention and is widely used in daily life. A photovoltaic panel cannot be popularized due to a high manufacturing cost leading to a high sale price. The high manufacturing cost of the photovoltaic panel is partially caused by a high encapsulation cost. Because the market requires the photovoltaic panel to be built on the roof of a building and operated for quite a long period of time (e.g. more than 20 years), excellent heat resistant and waterproof functions are needed, and thus the requirement standards for the selection, design and processing of an encapsulating material are very high.

However, if the high manufacturing cost of the photovoltaic panel is reflected on the sale prices of related products, the popularization of such products will negatively affected. It is desirable in this industry to reduce the manufacturing cost of the photovoltaic panel without sacrificing the functions of excellent heat resistance, waterproof and electrical insulation.

### SUMMARY

Therefore, an object of the present invention is to provide a photovoltaic panel with a low cost.

According to the above object, the present invention provides a photovoltaic panel, and the photovoltaic panel includes a substrate, a photovoltaic array, two bus bars, two interconnecting wires, two first insulation films, a first encapsulating film, a rear substrate and a junction box. The photovoltaic array is formed on the substrate. The two bus bars are formed on the substrate and are electrically connected to the photovoltaic array. The two interconnecting wires are respectively connected to the two bus bars. The two first insulation films are partially overlapped and are located between the two interconnecting wires and the photovoltaic array. The first encapsulating film covers the photovoltaic array, the two bus bars, the two interconnecting wires and the two first insulation films. The first encapsulating film has two first slits respectively for allowing the two interconnecting wires to pass through. The rear substrate covers the first encapsulating film and has at least one opening respectively for allowing the two interconnecting wires to pass through. The junction box is disposed on the rear substrate, and the two interconnecting wires are respectively electrically connected between the junction box and the two bus bars to output the current produced by the photovoltaic array.

According to another embodiment of the present invention, a length of one of the first insulation films is greater than a length of a portion of one of the interconnecting wires contacting the first insulation film.

According to another embodiment of the present invention, a length of one of the first insulation films is smaller than a spacing between the two bus bars.

According to another embodiment of the present invention, a total length of the two first insulation films which are partially overlapped is equal to a spacing between the two bus bars.

According to another embodiment of the present invention, the rear substrate includes a multilayer film plate, and the multilayer film plate has a thin metal plate laminated therein.

According to another embodiment of the present invention, the photovoltaic panel further includes a second insulation film disposed between the rear substrate and the first encapsulating film, and the second insulation film has two second slits respectively in for allowing the two interconnecting wires to pass through, thereby electrically insulating the thin metal plate in the rear substrate from the two interconnecting wires.

According to another embodiment of the present invention, the photovoltaic panel further includes a second encapsulating film disposed between the second insulation film and the rear substrate, and the second encapsulating film has two third slits respectively for allowing the two interconnecting wires to pass through.

According to another embodiment of the present invention, the rear substrate includes a glass substrate.

According to another embodiment of the present invention, the insulation film includes polyethylene terephthalate (PET).

According to another embodiment of the present invention, the encapsulating film includes ethylene-vinyl acetate copolymer (EVA).

As described above, in the application of the photovoltaic panel of the present invention, although the number of electrical insulation layers between the photovoltaic array layer and the interconnecting wires of the photovoltaic panel is reduced, the design of the two insulation films partially overlapped technically improves the electrical insulation of the key components, which will not sacrifice the electrical insulation quality but will effectively reduce the encapsulation cost.

### BRIEF DESCRIPTION OF THE DRAWINGS

The above and other objectives, features, advantages and embodiments of the present invention can be more fully understood with reference to the accompanying drawings as follows:

FIG. 1 is an explosive view of a photovoltaic panel according to an embodiment of the present invention; and

FIGS. 2A-2G are a series of flow charts of assembling the photovoltaic panel according to an embodiment of the present invention.

### DETAILED DESCRIPTION

According to the above description, the present invention provides a photovoltaic panel with a low encapsulation cost, which reduces the number and area of the insulation layers between the photovoltaic array layer and the interconnecting wires of the photovoltaic panel, thereby reducing the encapsulation cost. The embodiments of the present invention will be explained with reference to the accompanying drawings.

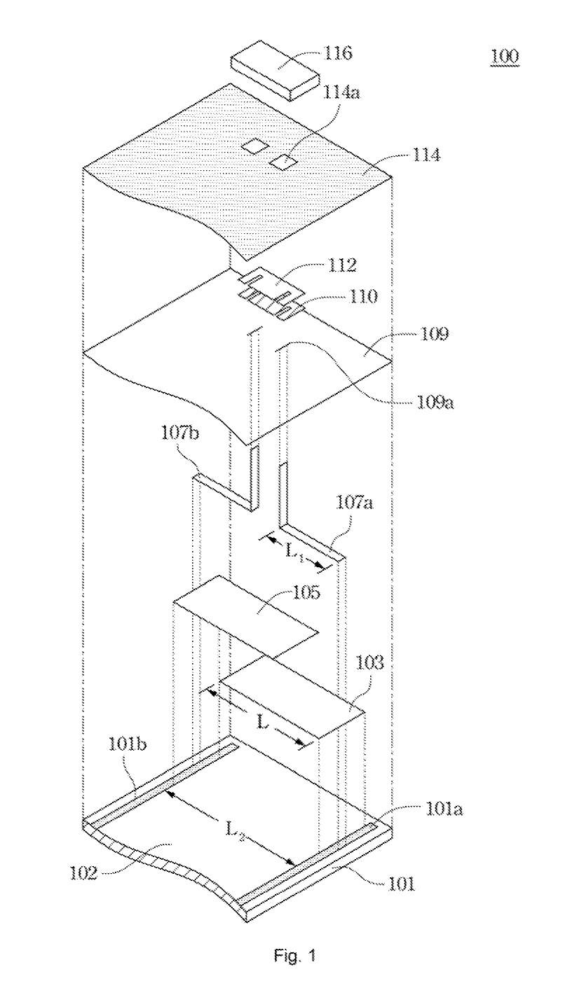

FIG. 1 is an explosive view of a photovoltaic panel according to an embodiment of the present invention. The photovoltaic panel 100 includes a substrate 101, two insulation films 103 and 105, two interconnecting wires 107a and 107b, an encapsulating film 109, an insulation film 110, an encapsulating film 112, a rear substrate 114 and a junction box 116 from bottom to top. A photovoltaic array 102 is formed on the substrate 101 for converting the received solar energy into electrical energy. Two bus bars 101a and 101b are formed on two sides of the substrate 101, and are electrically connected to the photovoltaic array 102 for collecting electrical energy. The two interconnecting wires 107a and 107b are metal wires, such as copper wires, copper foils or tinned copper wires or tinned copper foils. One end of the two interconnecting wires 107a and 107b is respectively connected to the two bus bars 101a and 101b, and the other end of the two interconnecting wires 107a and 107b is connected to the junction box 116, thereby transmitting the collected electrical energy from the two bus bars 101a and 101b to the junction box 116, thereby outputting it to the outside.

In this embodiment, the rear substrate 114 is a multilayer film plate, and the multilayer film plate has a thin metal plate laminated therein. To electrically insulating the thin metal plate in the rear substrate 114 from the two interconnecting wires 107a and 107b, the insulation film 110 is required to be disposed between the rear substrate 114 and the encapsulating film 109, and another encapsulating film 112 is also required to be disposed between the insulation film 110 and the rear substrate 114.

In other embodiments, the rear substrate 114 may be a glass substrate. The glass substrate does not contain a thin metal plate, so the glass substrate does not need to be electrically insulated from the two interconnecting wires 107a and 107b. Therefore, the insulation film 110 and the encapsulating film 112 are not essential components and can be omitted.

In this embodiment, the aforementioned insulation film may be a polyethylene terephthalate (PET) film. The aforementioned encapsulating film may be an ethylene-vinyl acetate copolymer (EVA) film.

In this embodiment, the two insulation films 103 and 105 function as an electrical insulation layer between the photovoltaic array layer 102 and the two interconnecting wires 107a and 107b of the photovoltaic panel. Compared with the design of a three-layered photovoltaic panel or an additional encapsulating film in the prior art, this embodiment only needs two insulation films 103 and 105 partially overlapped to achieve the same objective. The overlapped part of the two insulation films 103 and 105 are aligned with the bent part of the two interconnecting wires 107a and 107b, thereby providing double-layered electrical insulation. Since the bent part of the two interconnecting wires 107a and 107b may suffer an external stress and a large stress may be applied on the insulation film, a double-layered insulation film is required to ensure the electrical insulation between the photovoltaic array layer 102 and the two interconnecting wires 107a and 107b. Although the insulation film may have heat resistant and waterproof functions, yet electrical insulation function is mainly required between the photovoltaic array layer 102 and the two interconnecting wires 107a and in 107b. Therefore, the heat resistant and waterproof consideration and design will not be described herein.

In this embodiment, a length L of at least one of the two insulation films 103 or 105 is greater than a length L₁ of a portion of one of the two interconnecting wires 107a and 107b contacting the corresponding insulation film 103 or 105. To save the cost, the length L of at least one of the two insulation films 103 or 105 is smaller than a spacing L₂ between the two bus bars 101a and 101b. However, a total length of the two insulation films which are partially overlapped is equal to the spacing L₂ between the two bus bars 101a and 101b. Furthermore, a width of the two insulation films 103 and 105 needs to be greater than a width of the interconnecting wires 107a and 107b.

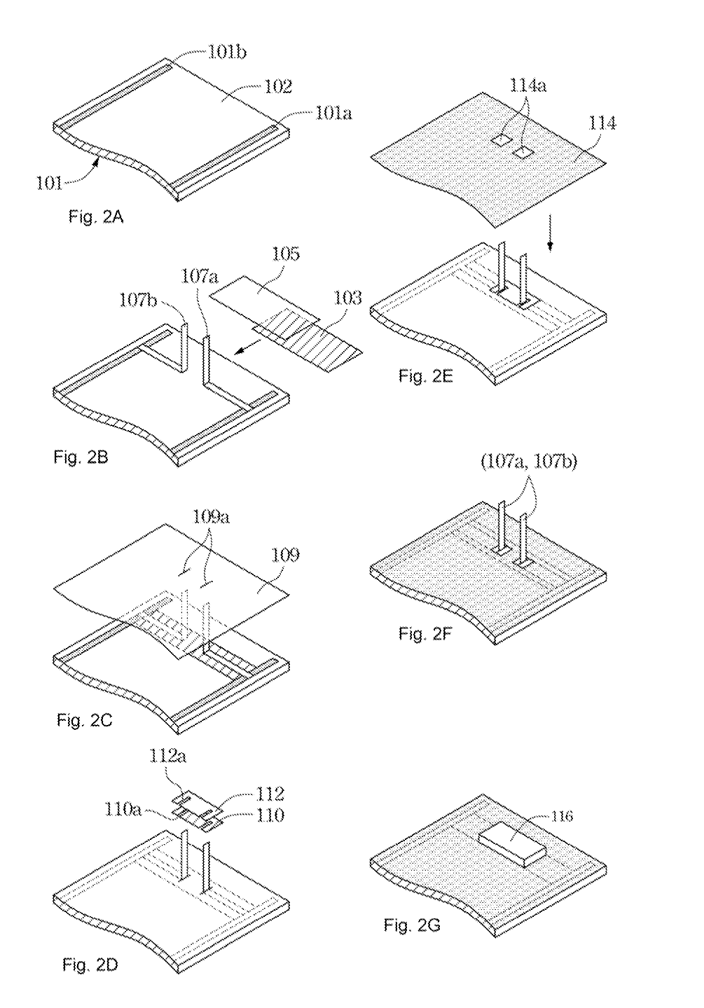

FIGS. 2A-2G are a series of flow charts of assembling the photovoltaic panel according to an embodiment of the present invention.

In FIG. 2A, the photovoltaic array 102 is formed on the substrate 101. Then, two bus bars 101a and 101b are formed at two sides of the substrate 101.

In FIG. 2B, one end of the interconnecting wires 107a and 107b is respectively welded on the two bus bars 101a and 101b, and the two insulation films 103 and 105 are partially overlapped.

In FIG. 2C, the overlapped two insulation films 103 and 105 are placed between the interconnecting wires 107a and 107b and the photovoltaic array 102, and the two ends of the overlapped insulation films 103 and 105 must be aligned with the two bus bars 101a and 101b. Furthermore, another encapsulating film 109 is covered on the photovoltaic array 102, two bus bars 101a and 101b, two interconnecting wires 107a and 107b and two insulation films 103 and 105, and the two interconnecting wires 107a and 107b pass through two slits 109a of the encapsulating film.

In FIG. 2D, the insulation film 110 cover the encapsulating film 109, and has two slits 110a respectively for allowing the two interconnecting wires 107a and 107b to pass through. The encapsulating film 112 covers the insulation film 110, and has two slits 112a respectively for allowing the two interconnecting wires 107a and 107b to pass through. In this embodiment, the area of the insulation film 110 and that of the encapsulating film 112 are substantially the same, but both are smaller than that of the encapsulating film 109.

In FIGS. 2E and 2F, a rear substrate 114 covers the encapsulating film 109 and the encapsulating film 112, and the rear substrate 114 has two openings 114a respectively for allowing the two interconnecting wires 107a and 107b to pass through. The encapsulating film 109, the insulation film 110 and the encapsulating film 112 are used to provide high-standard functions of heat resistance, waterproof and electrical insulation.

In another embodiment, an opening arranged on the rear substrate 114 may be a large opening, and the area is about a total sum of the area of the two openings 114a and the area therebetween, thereby allowing the two interconnecting wires 107a and 107b to pass through.

In FIG. 2G, a junction box 116 is assembled on the rear substrate 114, and the tail ends of the two interconnecting wires 107a and 107b that pass across the rear substrate 114 are respectively welded on two electrical contacts in the junction box 116, so as to output the current produced by the photovoltaic array 102.

As can be known from the above embodiments of the present invention, in the application of the photovoltaic panel of the present invention, although the number of electrical insulation layers between the photovoltaic array layer and the interconnecting wires of the photovoltaic panel is reduced, the design of two insulation films partially overlapped technically improves the electrical insulation of the key parts, which will not sacrifice the electrical insulation quality but will effectively reduce the encapsulation cost.

Although the present invention has been described in considerable detail with reference to certain embodiments thereof, other embodiments are possible. Various alternations and modifications can be made to these certain embodiments by those skilled in the art without departing from the spirit and scope of the present invention. Such alternations and modifications are intended to fall within the scope of the appended claims.

What is claimed is:

1. A photovoltaic panel, at least comprising:
a substrate;
a photovoltaic array formed on the substrate;
two bus bars formed on the substrate and electrically connected to the photovoltaic array;
two interconnecting wires respectively connected to the two bus bars;
two first insulation films partially overlapped and located between the two interconnecting wires and the photovoltaic array;
a first encapsulating film covering the photovoltaic array, the two bus bars, the two interconnecting wires and the two first insulation films, and having two first slits respectively for allowing the two interconnecting wires to pass through;
a rear substrate covering the first encapsulating film, and having at least one opening respectively for allowing the two interconnecting wires to pass through; and
a junction box disposed on the rear substrate, wherein the two interconnecting wires are respectively electrically connected between the junction box and the two bus bars to output current produced by the photovoltaic array.

2. The photovoltaic panel of claim 1, wherein a length of one of the first insulation films is greater than a length of a portion of one of the interconnecting wires contacting the first insulation film.

3. The photovoltaic panel of claim 2, wherein .a length of one of the first insulation films is smaller than a spacing between the two bus bars.

4. The photovoltaic panel of claim 1, wherein a total length of the two first insulation films which are partially overlapped is equal to a spacing between the two bus bars.

5. The photovoltaic panel of claim 1, wherein the rear substrate comprises:
a multilayer film plate, wherein the multilayer film plate has a thin metal plate laminated therein.

6. The photovoltaic panel of claim 5, further comprising:
a second insulation film disposed between the rear substrate and the first encapsulating film, wherein the second insulation film has two second slits respectively for allowing the two interconnecting wires to pass through, so as to electrically insulate the thin metal plate in the rear substrate from the two interconnecting wires.

7. The photovoltaic panel of claim 6, further comprising:
a second encapsulating film disposed between the second insulation film and the rear substrate and having two third slits respectively for allowing the two interconnecting wires to pass through.

8. The photovoltaic panel of claim 1, wherein the rear substrate comprises a glass substrate.

9. The photovoltaic panel of claim 1, wherein the insulation film comprises polyethylene terephthalate.

10. The photovoltaic panel of claim 1, wherein the encapsulating film comprises ethylene-vinyl acetate copolymer.
